(19) United States
(12) Patent Application Publication
(10) Pub. No.: US 2025/0164549 A1
(43) Pub. Date: May 22, 2025

(54) COOLING PLATE, WIRING BOARD ASSEMBLY AND DEVICE TESTING APPARATUS

(71) Applicant: ADVANTEST Corporation, Tokyo (JP)

(72) Inventors: Yasufumi Yoda, Tokyo (JP); Hidehiko Yasuno, Tokyo (JP); Katsushi Sugai, Tokyo (JP); Atsuyuki Doi, Tokyo (JP)

(73) Assignee: ADVANTEST Corporation, Tokyo (JP)

(21) Appl. No.: 18/949,857

(22) Filed: Nov. 15, 2024

(30) Foreign Application Priority Data
Nov. 17, 2023 (JP) 2023-196102

(51) Int. Cl. G01R 31/28

(52) U.S. Cl. CPC G01R 31/2877

(57) ABSTRACT

A cooling plate cools an electronic component for testing mounted on a wiring board used for testing a device under test (DUT), and includes: a first plate having a main surface having a first groove that forms a flow path through which a cooling liquid passes; a second plate disposed on the main surface of the first plate; and an adhesive part that bonds the first plate and the second plate.

### CROSS-REFERENCE TO RELATED APPLICATIONS

The present application claims priority from Japanese Patent Application No. 2023-196102 filed on Nov. 17, 2023, the contents of which are incorporated herein by reference in their entirety.

### BACKGROUND

### Technical Field

The present invention relates to a cooling plate that cools an electronic component for testing mounted on a wiring board used for testing a device under test (DUT), a wiring board assembly including the cooling plate, and a device testing apparatus including the wiring board assembly.

### Description of Related Art

A water jacket that is attached to a pin electronics card accommodated in a test head of an electronic device testing apparatus for testing a DUT and cools an electric component for testing mounted on the pin electronics card is known (refer to, for example, Patent Document 1).

### PATENT DOCUMENT

PATENT DOCUMENT 1: JP 2013-2946 A

The water jacket described above adopts a so-called immersion liquid cooling system in which a cooling liquid flows through a passage that accommodates an electric component for testing and the cooling liquid is brought into direct contact with the electric component for testing. As a result, a liquid having excellent electrical insulating properties, such as a fluorine-based inert liquid, is used as the cooling liquid, and thus it is difficult to reduce the load on the environment.

### SUMMARY

One or more embodiments of the present invention provide a cooling plate, a wiring board assembly and a device testing apparatus capable of reducing the load on the environment.

[1] Aspect 1 of the present invention is a cooling plate that cools an electronic component for testing mounted on a wiring board used for testing a device under test (DUT), the cooling plate comprising: a first plate having a main surface having a first groove that forms a flow path through which a cooling liquid passes; a second plate disposed on the main surface of the first plate; and an adhesive part that bonds the first plate and the second plate.

[2] Aspect 2 of the present invention may be the cooling plate of Aspect 1, wherein the second plate may have a second groove facing the first groove, and the first groove and the second groove may form the flow path.

[3] Aspect 3 of the present invention may be the cooling plate of Aspect 1 or 2, wherein the adhesive part may surround the flow path around an entire periphery of the flow path in a plan view.

[4] Aspect 4 of the present invention may be the cooling plate of any one of Aspects 1 to 3, wherein the adhesive part may comprise: a first extending part that is interposed between the first plate and the second plate and extends along one side of the flow path; and a second extending part that is interposed between the first plate and the second plate and extends along another side of the flow path.

[5] Aspect 5 of the present invention may be the cooling plate of Aspect 4, wherein the main surface of the first plate may have: a first recess extending along the one side of the first groove; and a second recess extending along the other side of the first groove, the first recess may accommodate at least part of the first extending part, and the second recess may accommodate at least part of the second extending part.

[6] Aspect 6 of the present invention may be the cooling plate of any one of Aspects 1 to 5, wherein the first plate may have a narrow groove formed on a bottom surface of the first groove.

[7] Aspect 7 of the present invention may be the cooling plate of any one of Aspects 1 to 6, wherein at least one of the first and second plates may have an air vent hole penetrating the at least one of the first and second plates, and the air vent hole may be formed between two extending parts of the adhesive part that are adjacent to each other.

[8] Aspect 8 of the present invention may be the cooling plate of any one of Aspects 1 to 7, wherein the flow path may have a meandering planar shape, at least one of the first and second plates may have an air vent hole penetrating the at least one of the first and second plates, and the air vent hole may be formed between two extending parts of the flow path that are adjacent to each other.

[9] Aspect 9 of the present invention is a wiring board assembly comprising: a first electronic component for testing; a first wiring board on which the first electronic component is mounted; and the cooling plate of any one of Aspects 1 to 8, wherein the first wiring board is disposed on the cooling plate such that the first electronic component is interposed between the first wiring board and the cooling plate.

[10] Aspect 10 of the present invention may be the wiring board assembly of Aspect 9, wherein the wiring board assembly may comprise a first heat transfer layer that contacts the first electronic component and contacts a first outer surface of the cooling plate.

[11] Aspect 11 of the present invention may be the wiring board assembly of Aspect 9 or 10, wherein the wiring board assembly may comprise: a second electronic component for testing; and a second wiring board on which the second electronic component is mounted, the second wiring board may be disposed on the cooling plate such that the second electronic component is interposed between the second wiring board and the cooling plate, and the cooling plate may be interposed between the first wiring board and the second wiring board.

[12] Aspect 12 of the present invention may be the wiring board assembly of Aspect 11, wherein the wiring board assembly may comprise a second heat transfer layer that contacts the second electronic component and contacts a second outer surface of the cooling plate.

[13] Aspect 13 of the present invention is a device testing apparatus that tests a device under test (DUT), the device testing apparatus comprising the wiring board assembly of any one of Aspects 9 to 12.

[14] Aspect 14 of the present invention may be the device testing apparatus of Aspect 13, wherein the device testing apparatus may comprise: a cooling liquid supply device that supplies a cooling liquid to the flow path in the cooling plate; and an ion removing filter that is interposed between the cooling liquid supply device and the wiring board assembly and removes ions from the cooling liquid.

[15] Aspect 15 of the present invention may be the device testing apparatus of Aspect 13 or 14, wherein the cooling liquid may be water.

[16] Aspect 16 of the present invention may be the device testing apparatus of any one of Aspects 13 to 15, wherein the device testing apparatus may comprise a test head that accommodates the wiring board assembly comprising: a pin electronics card, and the pin electronics card may comprise the first wiring board; and the first electronic component.

According to one or more embodiments of the present invention, the second plate is disposed on the main surface of the first plate having first groove that forms the flow path, and the cooling liquid is not in direct contact with the electronic component for testing. Therefore, it is possible to use water as the cooling liquid, and it is possible to reduce the load on the environment.

Further, according to one or more embodiments of the present invention, the cooling plate is constructed by bonding two plates together via the adhesive part. Therefore, even when water is used as the cooling liquid, it is possible to reduce the thickness of the cooling plate, and it is possible to arrange a plurality of the wiring boards at high density in the device testing apparatus.

### BRIEF DESCRIPTION OF DRAWINGS

FIG. 1 is a cross-sectional view showing the device testing apparatus in one or more embodiments of the present invention.

FIG. 2 is a cross-sectional view showing the test head taken along line II-II in FIG. 1 and is a block diagram showing the cooling system.

FIG. 3 is a partial cross-sectional view showing the testing module in one or more embodiments of the present invention and is a view taken along line III-III in FIG. 2.

FIG. 4 is a perspective view of the cooling plate in one or more embodiments of the present invention.

FIG. 5 is an exploded perspective view of the cooling plate in one or more embodiments of the present invention.

FIG. 6 is a partial exploded cross-sectional view showing the cooling plate in one or more embodiment of the present invention and is a view taken along line VI-VI in FIG. 5.

FIG. 7 is a partial exploded cross-sectional view showing the cooling plate in one or more embodiment of the present invention and is a view taken along line VII-VII in FIG. 5.

FIG. 8 is a partial cross-sectional view showing the cooling plate in another example of one or more embodiments of the present invention.

### DETAILED DESCRIPTION OF EMBODIMENTS

Hereinafter, embodiments of the invention will be described with reference to the drawings.

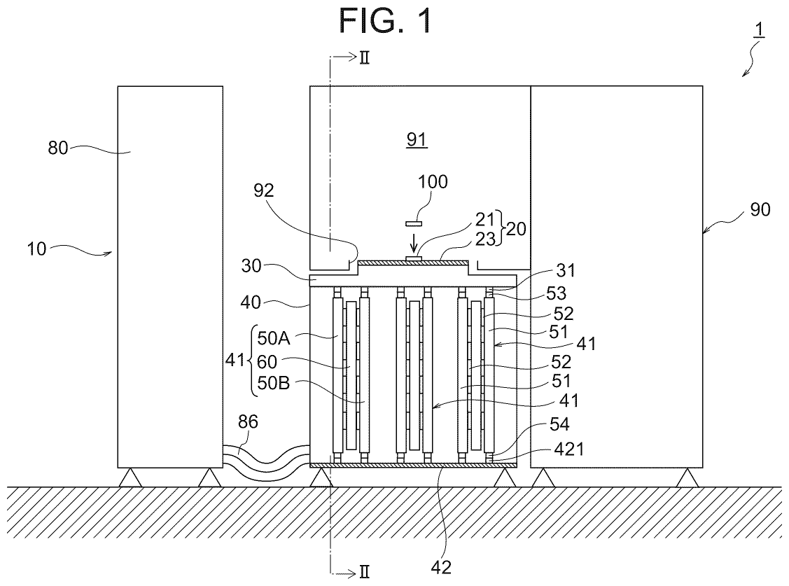

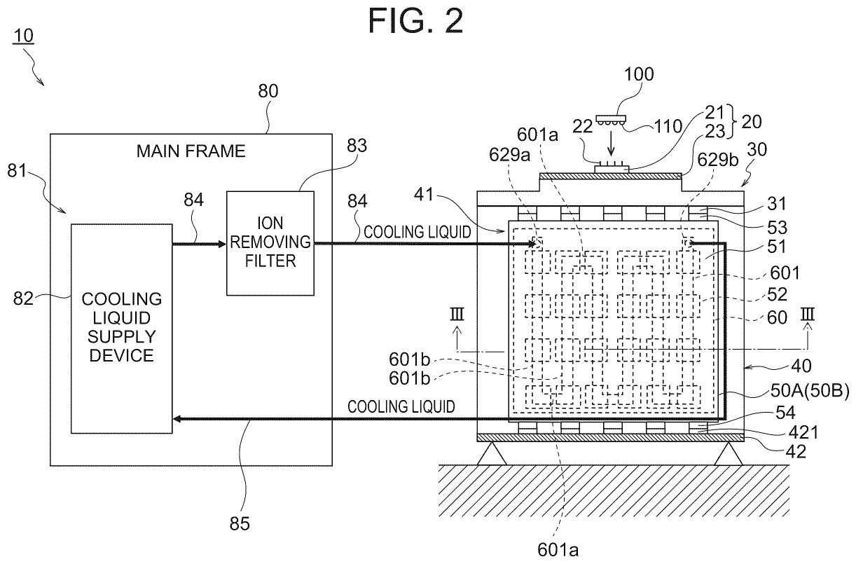

FIG. 1 is a cross-sectional view showing the device testing apparatus 1 in one or more embodiments of the present invention. FIG. 2 is a cross-sectional view showing the test head 40 taken along line II-II in FIG. 1 and is a block diagram showing the cooling system 81.

The device testing apparatus 1 in one or more embodiments is an apparatus that tests a device under test (hereinafter also simply referred to as “DUT”) 100. Although not particularly limited, a semiconductor device such as a memory device, a logic device, and SoC (System on chip) can be exemplified as a specific example of the DUT 100 to be tested. The device testing apparatus 1 tests the electrical characteristics of the DUT 100.

As shown in FIG. 1, the device testing apparatus 1 includes a tester 10 that tests the DUT 100, and a handler 90 that handles the DUT 100 and presses the DUT 100 against a socket 21. The tester 10 and the handler 90 may be electrically connected to a controller (computer) that includes a CPU (processor), a main memory (such as a RAM), an auxiliary memory device (such as a hard disk or SSD), an interface, and the like. The tester 10 includes a DSA 20, a motherboard 30, a test head 40, and a main frame 80. The configuration of the tester 10 is not particularly limited to the following as long as it includes the testing module 41 describer later.

As shown in FIG. 1 and FIG. 2, the DSA (Device Specific Adapter) 20 includes a socket 21 and a socket board 23. The DSA 20 is electrically connected to the test head 40 via the motherboard 30. The DSA 20 is detachable from the motherboard 30 via a connector (not shown). The DSA 20 is designed according to the type of the DUT 100, and the DSA 20 is replaced with one corresponding to the type when changing the type of DUT 100. The number of DSAs 20 mounted on the motherboard 30 is not particularly limited, and a plurality of DSAs 20 may be mounted on the motherboard 30.

When testing the DUT 100, the DUT 100 is pressed against the socket 21 by the handler 90, therefore the DUT 100 and the socket 21 are electrically connected. The socket 21 includes a plurality of contactors 22 that respectively contact terminals 110 of the DUT 100. Although not particularly limited, a pogo pin, a vertical-type probe needle, a cantilever-type probe needle, an anisotropic conductive rubber sheet, a bump disposed on a membrane, or a contactor manufactured using MEMS technology can be exemplified as a specific example of the contactor 22.

The socket board 23 is a wiring board with the above-described socket 21 mounted on its upper surface. The number of sockets 21 mounted on the socket board 23 is not particularly limited, and a plurality of sockets 21 may be mounted on one socket board 23. A socket guide (not shown) for positioning the DUT 100 with respect to the socket 21 may be mounted on the upper surface of the socket board 23. Although not particularly illustrated, the connector that is fitted with the connector of the mother board 30 is mounted on the lower surface of the socket board 23. The connector and the socket 21 are electrically connected via a conductive path (not shown) such as a wiring pattern and a through hole formed in the socket board 23.

The motherboard 30 is a relaying device that electrically connects the DSA 20 and the test head 40. The motherboard 30 includes an upper connector (not shown) that is fitted with the above-described connector of the socket board 23, a lower connector 31 that is connected to the test head 40, and coaxial cables that electrically connects these connectors.

As shown in FIG. 1 and FIG. 2, the test head 40 accommodates therein a testing module 111 for testing the DUT 100. Although the test head 40 includes three testing modules 41 in FIG. 1, the number of testing modules 41 included in the test head 40 is not particularly limited to this. Each of the testing modules 41 includes two pin electronics cards (pin electronics) 50A and 50B, and a cooling plate 60.

As shown in FIG. 1 and FIG. 2, each of the pin electronics cards 50A and 50B has upper connectors 53 that are fitted with the lower connectors 31 of the motherboard 30, and each of the pin electronics cards 50A and 50B is electrically connected to the motherboard 30. The pin electronics cards 50A and 50B test the DUT 100 by sending and receiving test signals to and from the DUT 100 via the DSA 20 and the motherboard 30. In addition, each of the pin electronics cards 50A and 50B has lower connectors 54 that are fitted with connectors 421 of a backboard 42 disposed at the bottom of the test head 40, and each of the pin electronics cards 50A and 50B is electrically connected to the backboard 42. The backboard 42 is connected to the mainframe 80 via a cable 86.

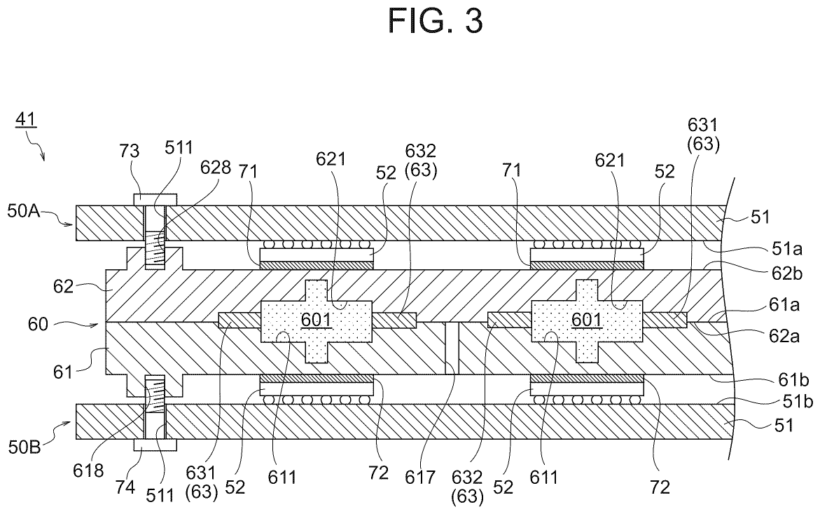

As shown in FIG. 2 and FIG. 3, the cooling plate 60 has a flow path 601 through which a cooling liquid (refrigerant) can pass. The cooling plate 60 is sandwiched between two pin electronics cards 50A and 50B. The cooling liquid supplied from a cooling system 81 (described later) of the main frame 80 flows through the flow paths 601 of the cooling plate 60 to cool the electronic components 52 for testing included in the pin electronics cards 50A and 50B. The configuration of the testing module 41 including the cooling plate 60 will be described in detail later.

The main frame (tester main body) 80 is, for example, a computer that executes a program, and the main frame 80 communicates with the pin electronics cards 50A and 50B in the test head 40 according to the program to control the pin electronics cards 50A and 50B. Each of the pin electronics cards 50A and 50B generates test signals according to instructions from the main frame 80 and inputs the test signals to the DUT 100. As shown in FIG. 2, the main frame 80 includes the cooling system 81 for supplying a cooling liquid to the cooling plate 60 described above.

Although not particularly illustrated, the handler 90 includes, for example, a transport device that transports the test tray on which the DUT 100 is mounted above the DSA 20, a pressing device that presses the DUT 100 against the socket 21 of the DSA 20, and a sorting device that sorts the DUT 100 according to the test result while taking the DUT 100 out from the test tray. As shown in FIG. 1, the handler 90 also includes a chamber 91 as a temperature adjusting device that applies high or low temperature thermal stress to the DUT 100. The chamber 91 includes a thermostatic chamber capable of maintaining the temperature in the chamber at a desired temperature. Therefore, the device testing apparatus 1 is capable of testing the DUT 100 while applying thermal stress to the DUT 100, and a so-called high-temperature test and a low-temperature test can be performed.

The DSA 20 enters the chamber 91 through an opening 92 formed in the handler 90, and the socket 21 of the DSA 20 is disposed in the chamber 91. The pressing device of the handler 90 presses the DUT 100 against the socket 21 of the DSA 20 to electrically connect the DUT 100 and the socket 21.

The handler 90 may be of a type where the handler 90 includes a contact arm that suction-holds and moves the DUT 100 without using a test tray and the contact arm presses the DUT 100. In this case, the handler 90 may include a heater or a heat sink disposed in the front end of the contact arm as a temperature adjusting device instead of the chamber 91. Alternatively, the handler 90 may include, in addition to the chamber 91, a heater or a heat sink disposed in the front end of the contact arm as a temperature adjusting device.

Next, the configuration of the testing module 41 described above will be described in detail with reference to FIG. 3 to FIG. 6 in addition to FIG. 1 and FIG. 2.

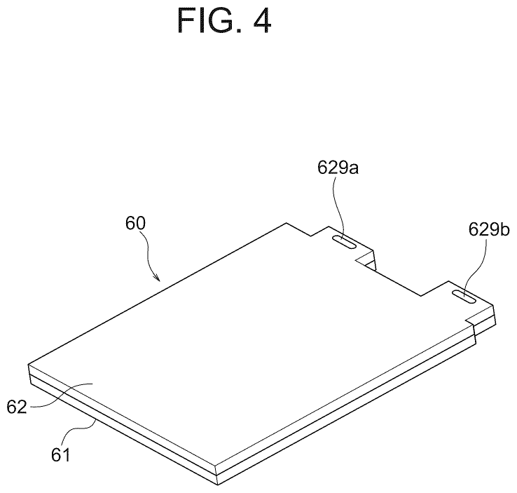

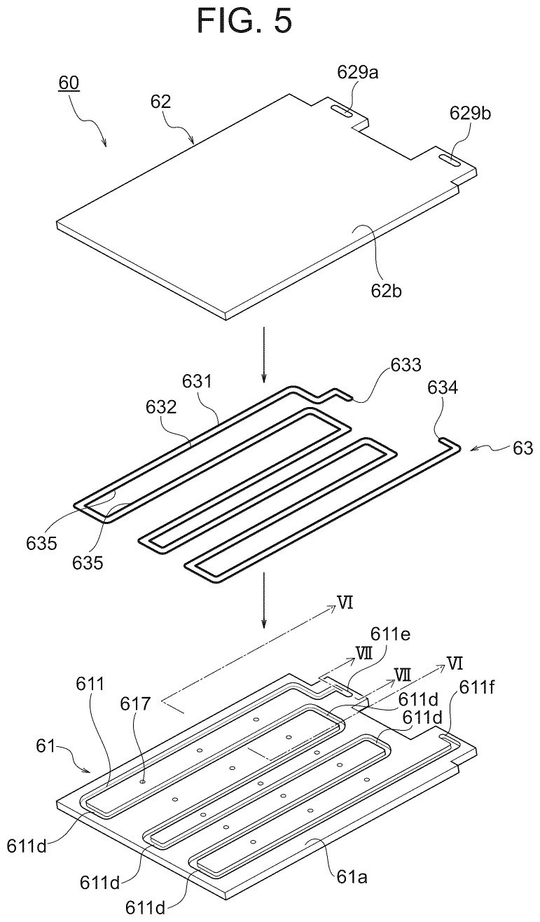

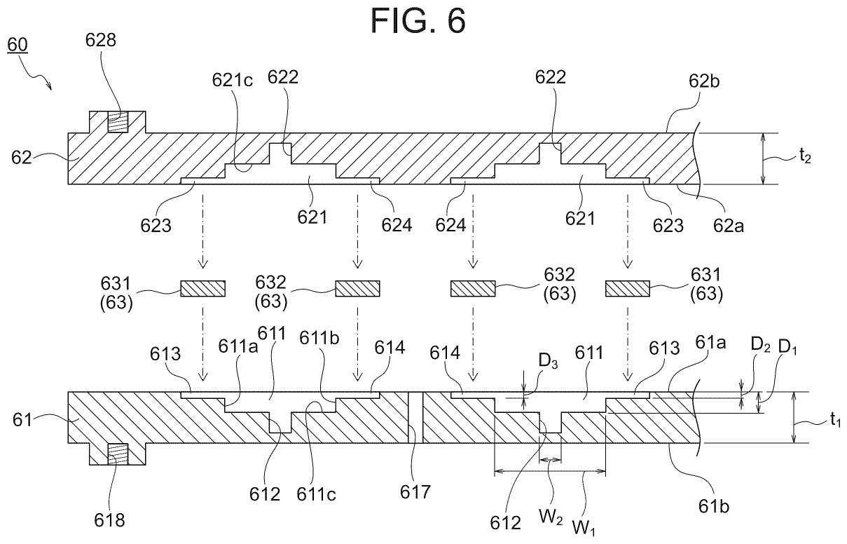

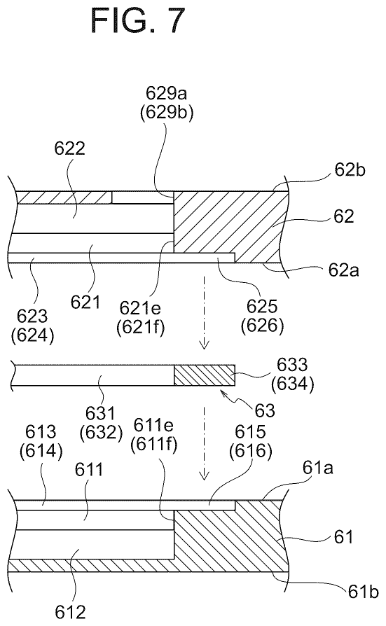

FIG. 3 is a partial cross-sectional view showing the testing module 41 in one or more embodiments and is a view taken along line III-III in FIG. 2. FIG. 4 is a perspective view of the cooling plate 60 in one or more embodiments. FIG. 5 is an exploded perspective view of the cooling plate 60 in one or more embodiments. FIG. 6 is a partial exploded cross-sectional view showing the cooling plate 60 in one or more embodiments and is a view taken along line VI-VI in FIG. 5. FIG. 7 is a partial exploded cross-sectional view showing the cooling plate 60 in one or more embodiments and is a view taken along line VII-VII in FIG. 5.

As described above, each of the testing modules 41 includes the two pin electronics cards 50 A and 50 B and the cooling plate 60. The cooling plate 60 is interposed between the two pin electronics cards 50 A and 50 B.

The testing module 41 adopts a so-called indirect liquid cooling system. That is, in the test module 41, the cooling liquid flows through the flow path 601 of the cooling plate 60, and the cooling liquid exchanges heat with the electronic components 52 of the pin electronic cards 50A and 50B via the cooling plate 60 to indirectly cool the electronic components 52. It is possible to use water as the cooling liquid by adopting the indirect liquid cooling system. Water to which an anticorrosive additive is added or deionized water may be used as the cooling liquid instead of ordinary water.

As shown in FIG. 1 to FIG. 3, The one pin electronic card 50A includes a wiring board 51, the electronic components 52 for testing, the upper connectors 53, and the lower connectors 54. The wiring board 51 is a wiring board including a substrate (base material) having electrical insulation properties and a conductive path such as a wiring pattern formed on the substrate. Although not particularly limited, a substrate made of glass epoxy resin, glass, or ceramics can be exemplified as a specific example of the substrate. The wiring board 51 of the pin electronic card 50A corresponds to an example of the “second wiring board” in one or more embodiments of the present invention, and the electronic component 52 of the pin electronic card 50A corresponds to an example of the “second electronic component” in one or more embodiments of the present invention.

A plurality of electronic components 52 used for testing the DUT 100 are mounted on the wiring board 51. In the pin electronics card 50A, the electronic components 52 are mounted on one main surface 51a (the lower surface 51a in FIG. 3) of the wiring board 51. The number and arrangement of the electronic components 52 mounted on the main surface 51a of the wiring board 51 are not particularly limited. For example, a high-frequency circuit (for example, ASIC (Application Specific Integrated Circuit)) in which LSI or the like for handling a test signal is incorporated, or a power supply circuit in which a switching regulator or the like for supplying power for testing to the DUT 100 is incorporated can be exemplified as a specific example of the electronic component 52.

The upper connectors 53 and lower connectors 54 are mounted on the wiring board 51. As shown in FIG. 1 and FIG. 2, the upper connectors 53 are mounted on the wiring board 51 such that the upper connectors 53 is arranged along the upper edge of the wiring board 51. On the other hand, the lower connectors 54 are mounted on the wiring board 51 such that the lower connectors 54 is arranged along the lower edge of the wiring board 51. As described above, the upper connector 53 is fitted with the lower connector 31 of the motherboard 30, while the lower connector 54 is fitted with the connector 421 mounted on the backboard 42.

As shown in FIG. 1 to FIG. 3, the other pin electronics card 50B has a configuration similar to that of the above-mentioned pin electronics card 50A and includes a wiring board 51, the electronic components 52 for testing, the upper connectors 53, and the lower connectors 54. In the pin electronics card 50B, the electronic components 52 are mounted on the other main surface 51b (upper surface 51b in FIG. 3) of the wiring board 51. The wiring board 51 of the pin electronics card 50B corresponds to an example of the “first wiring board” in one or more embodiments of the present invention, and the electronic component 52 of the pin electronics card 50B corresponds to an example of the “first electronic component” in one or more embodiments of the present invention.

The number of electronic components 52 mounted on the one pin electronics card 50A may be the same as or different from the number of electronic components 52 mounted on the other pin electronics card 50B. Further, the arrangement of the electronic component 52 mounted on the one pin electronic card 50A may be the same as or different from the arrangement of the electronic component 52 mounted on the other pin electronic card 50B.

As shown in FIG. 4 to FIG. 7, the cooling plate (cold plate) 60 is a cooler (heat exchanger) that includes a first plate 61, a second plate 62, and an adhesive part (or adhesive joint) 63. The first plate 61 and the second plate 62 are adhered (bonded) to each other by the adhesive part 63.

The first plate 61 is a plate-shaped member made of a metal material such as aluminum or an aluminum alloy. Similarly to the first plate 61, the second plate 62 is also a plate-like member made of a metal material such as aluminum or an aluminum alloy. In order to prevent corrosion of the cooling plate 60 by the cooling liquid, an oxide film, a coating layer, or a protective layer may be formed on the surfaces of the first and second plates 61 and 62.

Although not particularly limited, the first plate 61 has a thickness t₁ of 1.5 mm or more and 3.5 mm or less (1.5 mm≤t₁≤3.5 mm), and the second plate 62 also has a thickness t₂ of 1.5 mm or more and 3.5 mm or less (1.5 mm≤t₂≤3.5 mm). Although not particularly limited, in one or more embodiments, the thickness t₁ of the first plate 61 is 2.5 mm (t₁=2.5 mm), and the thickness t₂ of the second plate 62 is also 2.5 mm (t₂=2.5 mm), and as a result, the cooling plate 60 has a thickness of 5 mm.

A groove 611 and a pair of recesses 613 and 614 are formed on the inner surface 61a of the first plate 61. As shown in FIG. 5, the groove 611 extends linearly on the inner surface 61a of the first plate 61 and has a meandering (serpentine) planar shape that has a plurality of (five in one or more embodiments) folded parts 611d.

As shown in FIG. 6, the recess 613 extends along one side of the groove

611. The recess 613 extends over the entire longitudinal area (total length) of the groove 611 from one end 611e of the groove 611 to the other end 611f of the groove 611. On the other hand, the recess 614 extends along the other side of the groove 611. The recess 614 also extends over the entire longitudinal area (total length) of the groove 611 from one end 611e of the groove 611 to the other end 611f of the groove 611. Each of the recesses 613 and 614 has a meandering (serpentine) planar shape along the groove 611.

As shown in FIG. 7, a recess 615 is also formed in a portion of the inner surface 61a of the first plate 61 corresponding to one end 611e of the groove 611. One end of the recess 613 and one end of the recess 614 are connected via the recess 615. Similarly, a recess 616 is also formed in a portion of the inner surface 61a of the first plate 61 corresponding to the other end 611f of the groove 611. The other end of the recess 613 and the other end of the recess 614 are connected via the recess 616. That is, in a plan view, the groove 611 is surrounded (encircled) by the recesses 613 to 616 around the entire circumference of the groove 611. The recesses 613 to 616 are not shown in FIG. 5.

As shown in FIG. 6, the depth D₂ of the recess 613 is shallower than the depth D₁ of the groove 611 (D₂<D₁). The recess 613 opens to one side surface 611a of the groove 611. Similarly, the depth D₃ of the recess 614 is shallower than the depth D₁ of the groove 611 (D₃<D₁). The recess 614 opens to the other side surface 611b of the groove 611. Therefore, the recesses 613 and 614 communicate with the groove 611. The depths of the recesses 615 and 616 formed at both ends 611e and 611f of the groove 611 are also shallower than the depth D₁ of the groove 611. The recesses 615 and 616 communicate with the groove 611.

Similar to the first plate 61 described above, a groove 621 and a pair of recesses 623 and 624 are formed on the inner surface 62a of the second plate 62. Although not particularly illustrated, the groove 621 has a meandering (serpentine) planar shape that has a plurality of folded parts, and the planar shape of the groove 621 corresponds to the planer shape of the groove 611 of the first plate 61. In other words, the groove 621 has a planar shape in a mirror image relationship with the planer shape of the groove 611 of the first plate 61.

The recess 623 extends along one side of the groove 621. The recess 623 extends over the entire longitudinal area (total length) of the groove 621 from one end 621e of the groove 621 to the other end 621f of the groove 621. On the other hand, the recess 624 extends along the other side of the groove 621. The recess 624 also extends over the entire longitudinal area (total length) of the groove 621 from one end 621e of the groove 621 to the other end 621f of the groove 621. Each of the recesses 623 and 624 has a meandering (serpentine) planar shape along the groove 621. As shown in FIG. 7, recesses 625 and 626 are also respectively formed in a portion of the inner surface 62a of the second plate 62 corresponding to the both ends 621e and 621d of the groove 621. The recess 623 and the recess 624 are connected via the recesses 625 and 626. That is, in a plan view, the groove 621 is surrounded (encircled) by the recesses 623 to 626 around the entire circumference of the groove 621.

As shown in FIG. 5 to FIG. 7, the first plate 61 and the second plate 62 are stacked with the adhesive part 63 interposed therebetween. At this time, the first and second plates 61 and 62 are bonded together such that the inner surface 61a of the first plate 61 and the inner surface 62a of the second plate 62 face each other. The groove 611 of the first plate 61 and the groove 621 of the second plate 62 face each other, and the grooves 611 and 621 form the flow path 601 of the cooling plate 60. As shown in FIG. 2, the flow path 601 extends linearly in the cooling plate 60 and has a meandering (serpentine) planar shape that has a plurality of (five in one or more embodiments) folded parts 601a. Since it is possible to improve the flatness of both of the outer surfaces 61b and 62b of the cooling plate 60 by forming the flow path 601 using grooves 611 and 621 formed in the cooling plate 60, it is possible to use both of the outer surfaces 61b and 62b of the cooling plate 60 as cooling surfaces.

As shown in FIG. 5, the adhesive part 63 includes a first extending part 631, a second extending part 632, and connecting parts 633 and 634. As shown in FIG. 5 and FIG. 6, the first extending part 631 extends linearly along one side of the flow path 601. The first extending part 631 extends over the entire longitudinal area (total length) of the flow path 601 from one end of the flow path 601 to the other end of the flow path 601. On the other hand, the second extending part 632 extends linearly along the other side of the flow path 601. The second extending part 632 also extends over the entire longitudinal area (total length) of the flow path 601 from one end of the flow path 601 to the other end of the flow path 601. Each of the extending parts 631 and 632 has a meandering (serpentine) shape along the flow path 601.

One end of the first extending part 631 and one end of the second extending part 632 are connected by the connecting part 633. Similarly, the other end of the first extending part 631 and the other end of the second extending part 632 are connected by the connecting part 634. Therefore, the adhesive part 63 is sandwiched between the first and second plates 61 and 62 such that the adhesive part 63 surrounds (encircles) the flow path 601 around the entire circumference of the flow path 601 in a plan view. The flow path 601 is sealed by the adhesive part 63, and the leakage of the cooling liquid from the flow path 601 is suppressed. That is, the adhesive part 63 has the function of sealing the flow path 601 in addition to the function of bonding the first and second plates 61 and 62 together, and it is possible to reduce the number of components of the cooling plate 60.

As shown in FIG. 6, the recess 613 of the first plate 61 and the recess 623 of the second plate 62 face each other, and the recesses 613 and 623 accommodate the first extending part 631. Similarly, the recess 614 of the first plate 61 and the recess 624 of the second plate 62 face each other, and the recesses 614 and 624 accommodate the second extending part 632. Further, as shown in FIG. 7, the recesses 615 and 625 formed in the portions corresponding to the one ends 611e and 621e of the grooves 611 and 621 face each other, and the recesses 615 and 625 accommodate the connecting part 633. Similarly, the recesses 616 and 626 formed in the portions corresponding to the other ends 611f and 621f of the grooves 611 and 621 face each other, and the recesses 616 and 626 accommodate the connecting part 634.

Although not particularly limited, the adhesive is applied to all of the recesses 613 to 616 of the first plate 61 with a syringe, the first and second plates 61, 62 are stacked, and the adhesive is cured by heating to form the adhesive part 63. Since the first and second plates 61 and 62 are firmly bonded together by the adhesive part 63, bolts for fixing the first and second plates 61 and 62 are not required, and it is possible to reduce the number of components of the cooling plate 60.

As shown in FIG. 6 and FIG. 7, a narrow groove 612 is formed on the bottom surface 611c of the groove 611 of the first plate 61. The narrow groove 612 has a width W₂ narrower than a width W₁ of the groove 611 (W₂<W₁). Similarly, a narrow groove 622 narrower than the groove 621 is formed on the bottom surface 621c of the groove 621 of the second plate 62. Since the flow path 601 has the narrow grooves 612 and 622, even when the first and second plates 61 and 62 are thinned, it is possible to increase the contact area of the flow path 601 with the cooling liquid while ensuring a sufficient thickness of the portions of the first and second plates 61 and 62 corresponding to the bottom surfaces 621c and 622c of the grooves 611 and 621, therefore, it is possible to improve the cooling efficiency. The narrow grooves 612 and 622 are not shown in FIG. 5.

The narrow groove 612 or 622 may be formed only in one plate 61 or 62, and the narrow groove 622 or 612 may not be formed in the other plate 62 or 61. Alternatively, the narrow grooves 612 and 622 may not be formed in both of the plates 61 and 62.

As shown in FIG. 5 and FIG. 6, an air vent hole 617 is formed in the first plate 61. The air vent hole 617 penetrates the first plate 61 in the thickness direction of the first plate 61. The air vent hole 617 is formed between the opposing parts 635 (see FIG. 5) included in the adhesive part 63 that face each other in a plan view. The opposing parts 635 of the adhesive parts 63 are located between the opposing parts 601b (see FIG. 2) included in the flow path 601 that face each other in a plan view. When the first and second plates 61 and 62 are stacked on each other, air existing between the first and second plates 61 and 62 can be released to the outside through the air vent hole 617. Therefore, it is possible to prevent the adhesive from being pushed into the flow path 601 by the air, and it is possible to ensure good sealing performance by the adhesive part 63.

The air vent hole 617 may be formed in the second plate 62 instead of the first plate 61. Alternatively, the air vent holes 617 may be formed in both of the first and second plates 61 and 62.

As shown in FIG. 2, FIG. 4, FIG. 5, and FIG. 7, the second plate 62 has an inlet 629a at a position corresponding to one end of the flow path 601. Further, the second plate 62 has an outlet 629b at a position corresponding to the other end of the flow path 601. The inlet 629a is connected to the pipe 84 of the cooling system 81 described later, while the outlet 629b is connected to the pipe 85 of the cooling system 81.

As shown in FIG. 1 to FIG. 3, the two pin electronics cards 50A and 50B and the cooling plate 60 are stacked such that the cooling plate 60 is interposed between the pin electronics cards 50A and 50B. At this time, the one pin electronics card 50A is stacked on the cooling plate 60 such that the mounted surface 51a (lower side surface 51a in FIG. 3) of the wiring board 51 on which electronic components 52 are mounted faces the cooling plate 60. On the other hand, the other pin electronics card 50B is stacked on the cooling plate 60 such that the mounted surface 51b (upper side surface 51b in FIG. 3) of the wiring board 51 on which electronic components 52 are mounted faces the cooling plate 60.

A heat transfer member (or heat transfer layer) 71 is interposed between the electronic component 52 of the one pin electronics card 50A and the cooling plate 60. The heat transfer member 71 contacts the electronic component 52 and also contacts the outer surface 62b of the second plate 62. Similarly, a heat transfer member (or heat transfer layer) 72 is interposed between the electronic component 52 of the other pin electronics card 50B and the cooling plate 60. The heat transfer member 72 contacts the electronic component 52 and also contacts the outer surface 61b of the first plate 61.

For example, a thermal interface material (TIM) can be used as the heat transfer members 71 and 72. For example, a metal foil made of aluminum or copper, a graphite sheet, a silicone rubber sheet in which a thermally conductive filler is dispersed, a sheet containing carbon nanotubes (CNT), and a gel or paste in which a thermally conductive filler is dispersed can be used as the TIM. Although not limited, it is possible to improve the reliability of contact between the thinned first and second plates 61 and 62 and the DUT 100 by using a gel-like or paste-like TIM having less residual stresses after contact as the heat transfer members 71 and 72. The heat transfer member 71 corresponds to an example of the “second heat transfer member (or second heat transfer layer)” in one or more embodiments of the present invention, and the heat transfer member 72 corresponds to an example of the “first heat transfer member (or first heat transfer layer)” in one or more embodiments of the present invention.

As shown in FIG. 3, the one pin electronics card 50A is fixed to the cooling plate 60 by screwing the bolt 73 inserted into an insertion hole 511 of the pin electronics card 50A into the screw hole 628 of the second plate. Similarly, the other pin electronics card 50B is fixed to the cooling plate 60 by screwing the bolt 74 inserted into the insertion hole 511 of the pin electronics card 50B into the screw hole 618 of the first plate 61. The method of fixing the pin electronics cards 50A and 50B to the cooling plate 60 is not particularly limited to the above.

The cooling liquid is supplied from the cooling system 81 included in the main frame 80 to the flow path 601 of the cooling plate 60 of the test module 41 described above. As shown in FIG. 2, the cooling system 81 includes a cooling liquid supply device 82 and an ion removing filter 83. The cooling liquid supply device 82 includes, for example, a heat exchanger for cooling the cooling liquid and a pump for circulating the cooling liquid. Although not limited, the cooling liquid supply device 82 is, for example, a chiller.

The cooling liquid supply device 82 is connected to the flow path 601 of the cooling plate 60 via the pipes 84 and 85. Specifically, the pipe 84 connected to the cooling liquid supply device 82 is connected to the inlet 629a of the cooling plate 60. Further, the pipe 85 connected to the cooling liquid supply device 82 is connected to the outlet 629b of the cooling plate 60. Water can be exemplified as a specific example of the cooling liquid supplied from the cooling liquid supply device 82 to the flow path 601.

The ion removing filter 83 is disposed in the pipe 84. The ion removing filter 83 includes an ion exchange resin and can remove impurity ions (ionic impurities) from the water supplied from the cooling liquid supply device 82. Here, the corrosion of the cooling plate 60 due to the water is suppressed by the oxide film formed on the surfaces of the first and second plates 61 and 62. However, if the oxide film is damaged, the cooling plate 60 may be corroded due to the impurity ions contained in the water. On the other hand, in one or more embodiments, since the ion removing filter 84 removes the impurity ions from the water, it is possible to further suppress corrosion of the cooling plate 60 caused by the cooling liquid.

The cooling liquid supplied from the cooling liquid supply device 82 first flows into the flow path 601 of the cooling plate 60 via the pipe 84. At this time, since the water as the cooling liquid passes through the ion removing filter 83, the impurity ions are removed from the water. The cooling liquid then exchanges heat with the electronic components 52 of the pin electronics cards 50A and 50B through the first and second plates 61 and 62 while flowing through the flow path 601, therefore the cooling liquid cools the electronic components 52. That is, the cooling liquid flowing through the flow path 601 indirectly cools the electronic components 52 without directly contacting the electronic components 52. The cooling liquid that reaches the outlet 629b of the cooling plate 60 is then collected to the cooling liquid supply device 82 via the pipe 85, is cooled by the cooling liquid supply device 82, and is then supplied again to the pipe 84.

As described above, in one or more embodiments, the grooves 611 and 621 that face each other form the flow path 601, and the cooling liquid does not come into direct contact with the electronic components 52 for testing. Therefore, it is possible to use water as the cooling liquid, and it is possible to reduce the load on the environment.

In one or more embodiments, the cooling plate 60 is constituted by bonding two plates 61 and 62 together via the adhesive part 63. Therefore, even when water is used as the cooling liquid (i.e., when the indirect liquid cooling system is adopted as the cooling system), it is possible to thin the cooling plate 60, and it is possible to arrange the pin electronics cards 50A and 50B at high density in the test head 40.

Further, in one or more embodiments, since the cooling plate 60 is constituted by only the two plates 61 and 62 and the adhesive 63, it is possible to reduce the number of components constituting the cooling plate 60. Further, in one or more embodiments, since the cooling plate 60 has a simple configuration including two plates 61 and 62 and an adhesive 63, it is possible to further suppress the leakage of the cooling liquid from the cooling plate 60.

It should be noted that the embodiments described above are described to facilitate understanding of the invention and are not described to limit the invention. It is therefore intended that the elements disclosed in the above embodiments include all design modifications and equivalents to fall within the technical scope of the present invention.

Although not particularly illustrated, for example, the test module 41 may be configured by stacking only one of the pin electronics cards 50A or 50B on the cooling plate 60. In this case, the test module 41 does not include the other pin electronics card 50B or 50A.

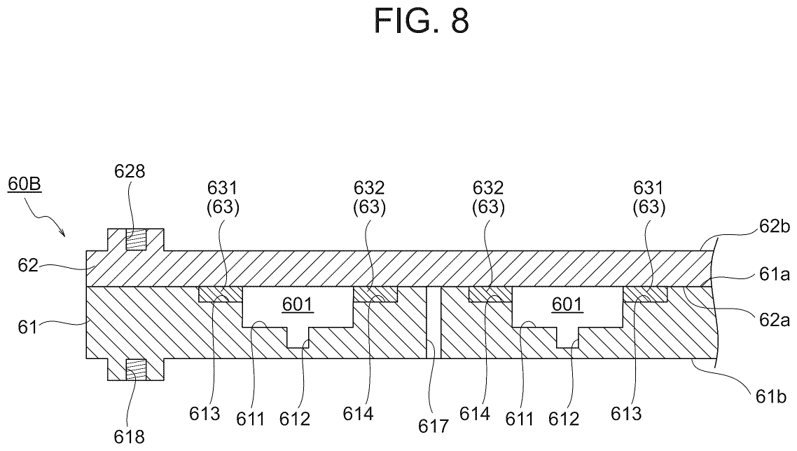

Although the grooves 611 and 621 are formed in both the first and second plates 61 in the above-described embodiments, for example, the groove 611 may be formed only in the first plate 61 as shown in FIG. 8. FIG. 8 is a partial cross-sectional view showing the cooling plate 60B in another example of one or more embodiments of the present invention.

In this case, as shown in FIG. 8, the first plate 61 has a configuration similar to that of the embodiments described above and has a groove 611 on the inner surface 61a of the first plate 61. On the other hand, the groove 621 is not formed on the inner surface 62a of the second plate 62. The recesses 623 and 624 and the narrow groove 622 are not also formed on the inner surface 62a of the second plate 62. The second plate 62 is stacked on the inner surface 61a of the first plate 61 such that the groove 611 is closed by the second plate 62. Since the cooling liquid does not come into direct contact with the electronic components 52 by stacked the second plate 62 on the inner surface 61a of the first plate 61 in which the groove 611 is formed to form the flow path 601, it is possible to use water as the cooling liquid, and it is possible to reduce the load on the environment.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATIONS OF LETTERS OR NUMERALS

1 . . . Device testing apparatus
10 . . . Tester
40. . . Test head
41 . . . Testing module
50A and 50B . . . Pin electronics cards
51 . . . Wiring board
52 . . . Electronic component
60 . . . Cooling Plate
601 . . . Flow path
601b . . . Opposing part
61 . . . First plate
611 . . . Groove
612 . . . Narrow groove
613 to 616 . . . Recesses
617 . . . Air vent hole
62 . . . Second plate
621 . . . Groove
622 . . . Narrow groove
623 to 626 . . . Recesses
63 . . . Adhesive part
631 and 632 . . . Extending parts
633 and 634 . . . Connecting parts
635 . . . Opposing part
71 and 72 . . . Heat transfer members
80 . . . Main frame
81 . . . Cooling system
82 . . . Cooling liquid supply device
83 . . . Ion removing filter
90 . . . Handler
100 . . . DUT

What is claimed is:

1. A cooling plate that cools an electronic component for testing mounted on a wiring board used for testing a device under test (DUT), the cooling plate comprising:
a first plate having a main surface having a first groove that forms a flow path through which a cooling liquid passes;
a second plate disposed on the main surface of the first plate; and
an adhesive part that bonds the first plate and the second plate.

2. The cooling plate according to claim 1, wherein
the second plate has a second groove facing the first groove, and
the first groove and the second groove form the flow path.

3. The cooling plate according to claim 1 wherein
the adhesive part surrounds the flow path around an entire periphery of the flow path in a plan view.

4. The cooling plate according to claim 1, wherein
the adhesive part comprises:
a first extending part that is interposed between the first plate and the second plate and extends along one side of the flow path; and
a second extending part that is interposed between the first plate and the second plate and extends along another side of the flow path.

5. The cooling plate according to claim 4, wherein
the main surface of the first plate has:
a first recess extending along the one side of the first groove; and
a second recess extending along the other side of the first groove,
the first recess accommodates at least part of the first extending part, and
the second recess accommodates at least part of the second extending part.

6. The cooling plate according to claim 1, wherein
the first plate has a narrow groove formed on a bottom surface of the first groove.

7. The cooling plate according to claim 1, wherein
at least one of the first and second plates has an air vent hole penetrating the at least one of the first and second plates, and
the air vent hole is formed between two extending parts of the adhesive part that are adjacent to each other.

8. The cooling plate according to claim 1, wherein
the flow path has a meandering planar shape,
at least one of the first and second plates has an air vent hole penetrating the at least one of the first and second plates, and
the air vent hole is formed between two extending parts of the flow path that are adjacent to each other each other.

9. A wiring board assembly comprising:
a first electronic component for testing;
a first wiring board on which the first electronic component is mounted; and
the cooling plate according to claim 1, wherein
the first wiring board is disposed on the cooling plate such that the first electronic component is interposed between the first wiring board and the cooling plate.

10. The wiring board assembly according to claim 9, further comprising:
a first heat transfer layer that contacts the first electronic component and contacts a first outer surface of the cooling plate.

11. The wiring board assembly according to claim 9, further comprising:
a second electronic component for testing; and
a second wiring board on which the second electronic component is mounted, wherein
the second wiring board is disposed on the cooling plate such that the second electronic component is interposed between the second wiring board and the cooling plate, and
the cooling plate is interposed between the first wiring board and the second wiring board.

12. The wiring board assembly according to claim 11, further comprising:
a second heat transfer layer that contacts the second electronic component and contacts a second outer surface of the cooling plate.

13. A device testing apparatus that tests a device under test (DUT), the device testing apparatus comprising:
the wiring board assembly according to claim 9.

14. The device testing apparatus according to claim 13, further comprising:
a cooling liquid supply device that supplies a cooling liquid to the flow path in the cooling plate; and
an ion removing filter that is interposed between the cooling liquid supply device and the wiring board assembly and removes ions from the cooling liquid.

15. The device testing apparatus according to claim 13, wherein the cooling liquid is water.

16. The device testing apparatus according to claim 13, further comprising:
a test head that accommodates the wiring board assembly comprising a pin electronics card, wherein
the pin electronics card comprises:
the first wiring board; and
the first electronic component.
